(19) United States
(12) Patent Application Publication
(10) Pub. No.: US 2011/0019709 A1
(43) Pub. Date: Jan. 27, 2011

(54) Semiconductor device and method of manufacturing the same

(75) Inventors: Yuji Masui, Kanagawa (JP); Takahiro Arakida, Kanagawa (JP); Naoki Jogan, Kanagawa (JP); Rintaro Koda, Tokyo (JP); Kouichi Kondo, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/805,029

(22) Filed: Jul. 8, 2010

(30) Foreign Application Priority Data
Jul. 23, 2009 (JP) 2009-172407

(51) Int. Cl. H01S 5/02; H01L 33/62; H01L 31/02

(52) U.S. Cl. 372/46.01; 257/99; 257/459; 257/E33.066; 257/E31.113

(57) ABSTRACT

The present invention provides a method of manufacturing a semiconductor device realizing improved yield. The semiconductor device includes: a substrate having a top face, an under face, and side faces; an optical function unit formed on the top face; a plurality of electrode pads formed on the under face; and a wiring formed on at least the side face and electrically connecting the optical function unit and at least one of the plurality of electrode pads.

### BACKGROUND OF THE INVENTION

1. Field of the Invention

The present invention relates to a semiconductor device having electrode pads and function parts (a light emission layer, a light reception layer, and an integrated circuit) on the surface and the rear face of a substrate and also having, on its side faces of the substrate, wirings electrically connecting them, and to a method of manufacturing the same.

2. Description of the Related Art

In a vertical cavity surface laser diode (VCSEL), a post-shaped mesa is formed on the substrate. Multilayer reflectors are formed in upper and lower parts of the mesa, and an active layer as a light emitting region is formed between the multilayer reflectors. Further, a ring-shaped upper electrode is formed on the top face of the mesa, and a lower electrode is formed on the rear face of the substrate. In the laser diode, current is injected from the upper and lower electrodes to the active layer, thereby generating light by recombination of electrons and holes. The light is reflected by the pair of multilayer reflectors, laser oscillation occurs at a predetermined wavelength, and the light is emitted as a laser beam from the top face of the mesa to the outside.

In the laser diode, in the case where an electrode pad is formed on only one of the rear face and the surface (the face on the mesa side) of the substrate, flip chip bonding using Au bumps is possible. Since the flip chip bonding does not necessitate wiring, the mounting cost is reduced, and the high frequency characteristic is excellent. In a laser diode of the 980 nm band, a GaAs substrate transmits generated light. Consequently, by using the substrate side as a light emission face and forming an electrode pad on the mesa side, flip chip bonding is possible. However, in laser diodes of the 780 nm band and the 850 nm band, a GaAs substrate absorbs generated light. Consequently, it is necessary to use the mesa side as a light emission face, form a through electrode in the substrate, and form an electrode pad on the rear face of the substrate via the through electrode (see Japanese Unexamined Patent Application Publication. No. 2003-142775).

### SUMMARY OF THE INVENTION

To form the through electrode, a through hole has to be formed in a substrate by etching, and a metal film has to be formed on the side face of the through hole. However, in the case where the thickness of the substrate is about 100 μm, the diameter of the through hole also becomes about 100 μm, so that the chip size has to be set to a size in which a through hole is able to be formed. As a result, a disadvantage such that the yield of chips per wafer deteriorates occurs.

Such a disadvantage occurs not only in a VCSEL but also in all of semiconductor devices n through electrodes.

It is desirable to provide a semiconductor device realizing increased yield and a method of manufacturing the same.

A semiconductor device of an embodiment of the present invention has a substrate having a top face, an under face, and side faces. The semiconductor device has: an optical function unit formed on the top face; a plurality of electrode pads formed on the under face; and a wiring formed on at least the side face and electrically connecting the optical function unit and at least one of the plurality of electrode pads.

In the semiconductor device of an embodiment of the invention, by the wiring formed on at least the side face of the substrate, the optical function unit formed on one of the faces of the substrate and the electrode pad on the other face side of the substrate are electrically connected to each other without forming a through electrode. Therefore, it is unnecessary to set the chip size to a size in which a through electrode is able to be formed.

A first method of manufacturing a semiconductor device of an embodiment of the invention includes the following steps (A1) to (A3):

(A1) a first step of forming an optical function unit on a top face of a substrate having the top face and an under face in each of chip regions surrounded by cutting regions in a lattice shape along which the substrate is to be cut, and forming a plurality of first metal layers over the cutting regions in the top face;
(A2) a second step of forming through holes from which a face on the substrate side of the first metal layer is exposed, in places including the cutting regions in the substrate, forming a plurality of electrode pads in the under face in each of the chip regions, and forming a second metal layer that electrically connects the first metal layer and the electrode pads via the through holes; and
(A3) a third step of cutting the substrate along the cutting regions and cutting at least the first metal layer out of the first and second metal layers to dice the substrate into chips.

In the first method of manufacturing a semiconductor device of an embodiment of the invention, at the time of dicing a substrate into chips, at least the first metal layer out of the first and second metal layers as a through electrode formed in a through hole is cut. It is therefore unnecessary to set the chip size to a size in which a through electrode is able to be formed.

A second method of manufacturing a semiconductor device of an embodiment of the present invention includes the following steps (B1) to (B2);

(B1) a first step of forming an optical function unit on a top face of a substrate having the top face and an under face in each of chip regions surrounded by cutting regions in a lattice shape along which the substrate is to be cut, forming a plurality of dents over the cutting regions in the top face of the substrate, and forming a plurality of metal layers extending from the optical function unit to a bottom face of the dent;
(B2) a second step of exposing a face on a bottom face side of the dent in the metal layer by etching the substrate, after that, forming a plurality of electrode pads on the under face in each of the chip regions, and making at least one of the plurality of electrode pads formed in each of the chip regions come in contact with the metal layer; and
(B3) a third step of cutting the substrate along the cutting regions and cutting the dents to dice the substrate into chips.

In the second method of manufacturing a semiconductor device of an embodiment of the invention, at the time of dicing a substrate into chips, the dents are cut. Therefore, it is unnecessary to set the chip size to a size in which a through electrode is able to be formed.

In the semiconductor device, the first method of manufacturing a semiconductor device, and the second method of manufacturing a semiconductor device of embodiments of the invention, it is unnecessary to set the chip size to a size in which a through electrode is able to be formed. Consequently, as compared with the case where a through electrode is formed in a chip, the chip size is smaller, and the yield improves.

Other and further objects, features and advantages of the invention will appear more fully from the following description.

### BRIEF DESCRIPTION OF THE DRAWINGS

FIG. 1 is a top view of a laser diode according to a first embodiment of the present invention.

FIG. 2 is a back side view of the laser diode illustrated in FIG. 1.

FIG. 3 is a cross section taken along line A-A of the laser diode of FIG. 1.

FIG. 4 is a cross section taken along line B-B of the laser diode of FIG. 1.

FIGS. 5A and 5B are cross sections for explaining a process of manufacturing the laser diode of FIG. 1.

FIGS. 6A and 6B are cross sections for explaining a process subsequent to FIGS. 5A and 5B.

FIGS. 7A and 7B are cross sections for explaining a process subsequent to FIGS. 6A and 6B.

FIGS. 8A and 8B are cross sections for explaining a process subsequent to FIGS. 7A and 7B.

FIG. 9 is a top view of the substrate in FIGS. 8A and 8B.

FIG. 10 is a rear view of the substrate in FIGS. 8A and 8B.

FIG. 11 is a top view of a modification of the laser diode in FIG. 1.

FIG. 12 is a rear view of the laser diode in FIG. 11.

FIG. 13 is a top view in a process of manufacturing the laser diode in FIG. 11.

FIG. 14 is a rear view of a substrate in FIG. 13.

FIG. 15 is a top view of a laser diode in a second embodiment of the invention.

FIG. 16 is a rear view of the laser diode in FIG. 15.

FIG. 17 is a cross section taken along line A-A of the laser diode in FIG. 15.

FIG. 18 is a cross section taken along line B-B of the laser diode in FIG. 15.

FIGS. 19A and 19B are cross sections for explaining a process of manufacturing the laser diode in FIG. 15.

FIGS. 20A and 20B are cross sections for explaining a process subsequent to FIGS. 19A and 19B.

### DETAILED DESCRIPTION OF THE PREFERRED EMBODIMENTS

Modes for carrying out the invention will be described in detail below with reference to the drawings. The description will be given in the following order.

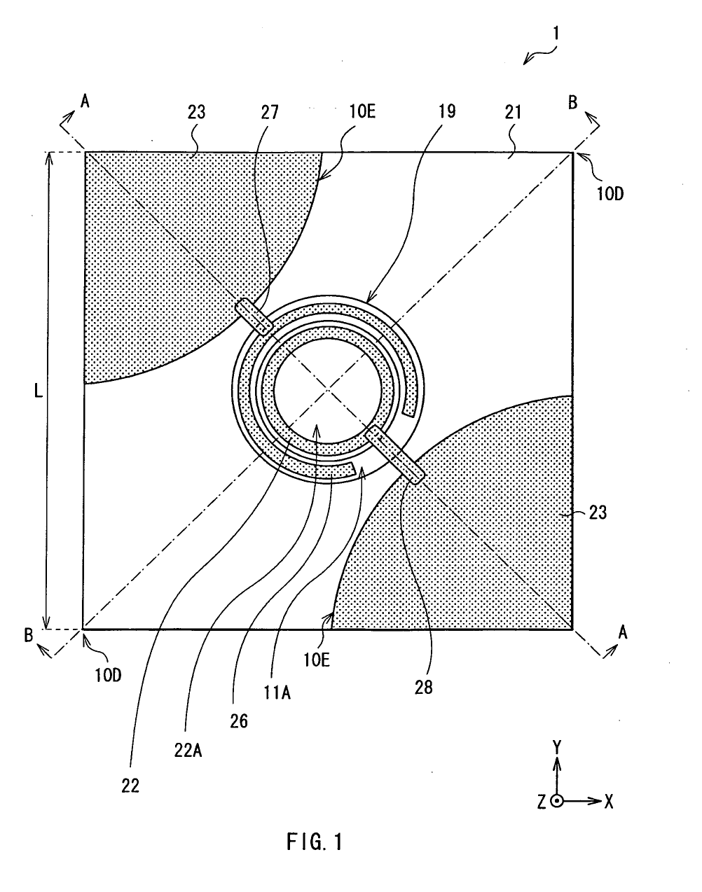

1. First embodiment (FIGS. 1 to 10)
Example in which a part of a through electrode is formed at a corner of a chip
Example in which a joint face of a through electrode is positioned on the top face side of a substrate

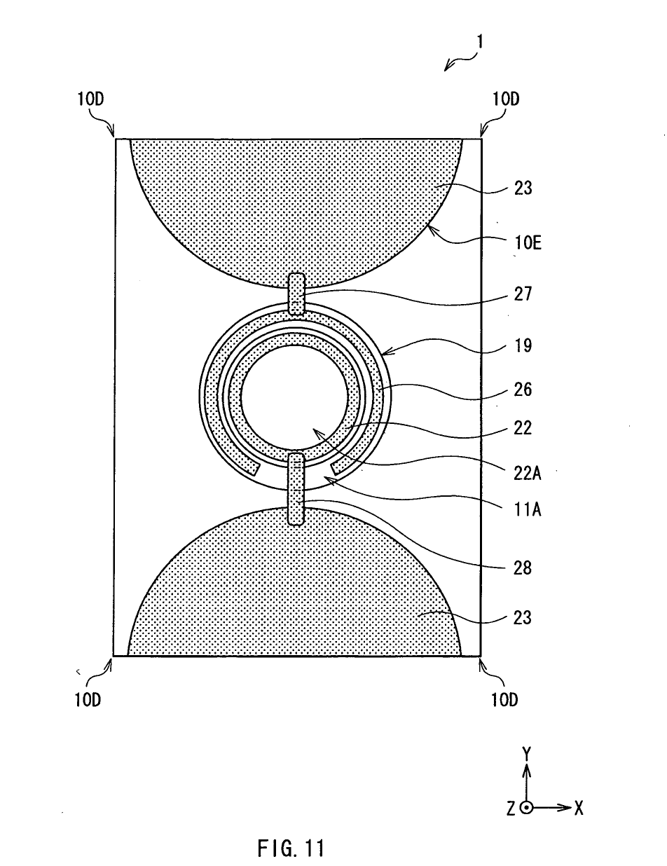

2. Modification of the first embodiment (FIGS. 11 to 14)
Example in which a part of a through electrode is formed in a side of a chip

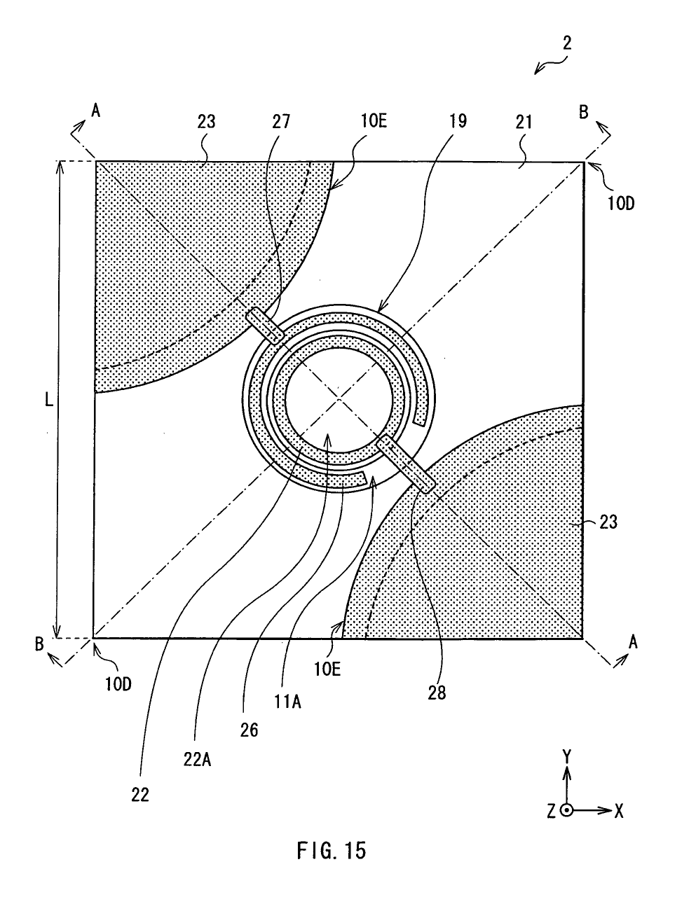

3. Second embodiment (FIGS. 15 to 20)
Example in which a part of a through electrode is formed at a corner of a chip
Example in which a joint face of a through electrode is positioned on the under face side of a substrate

4. Modification of the second embodiment
Example in which a part of a through electrode is formed in a side of a chip

### First Embodiment

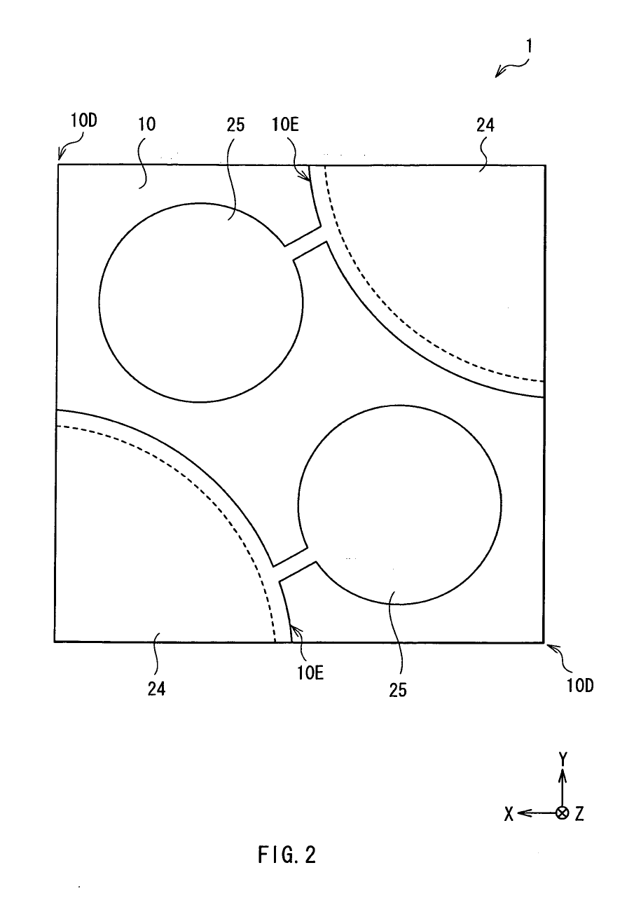

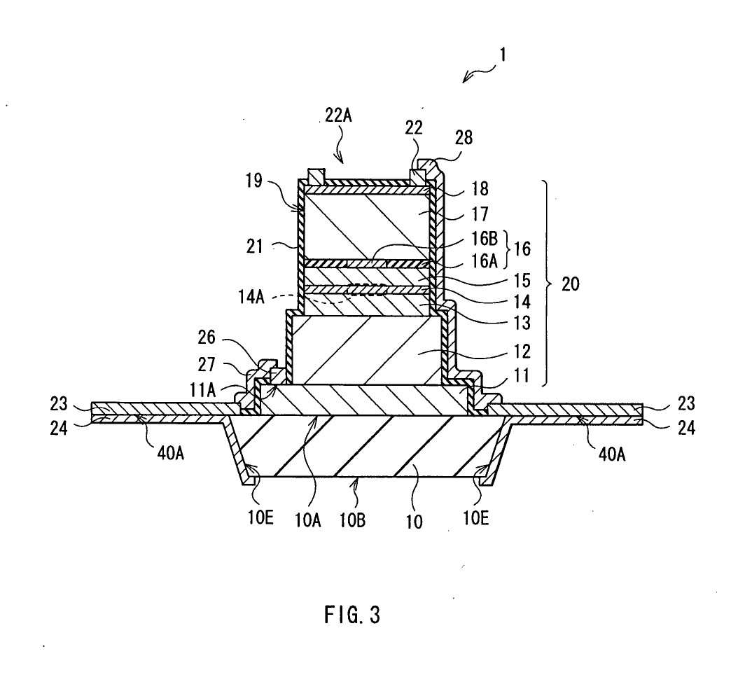

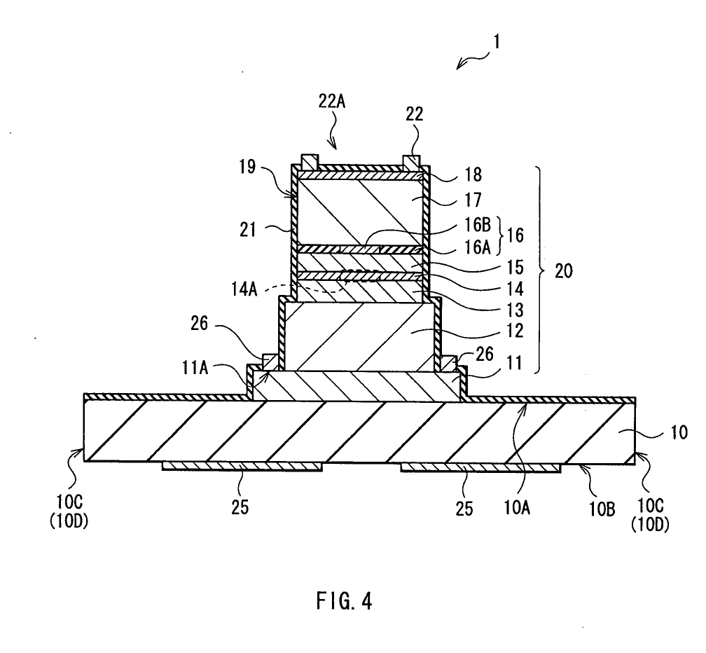

FIG. 1 is a top view of a vertical cavity surface laser diode 1 according to a first embodiment of the present invention. FIG. 2 is a back side view of the laser diode 1. FIG. 3 is a cross section taken along line A-A of the laser diode 1 of FIG. 1. FIG. 4 is a cross section taken along line B-B of the laser diode 1 of FIG. 1.

The laser diode 1 is a chip having a structure suitable for flip chip bonding. For example, the laser diode 1 has one or more mesas 19 (which will be described later) on the top face side of a substrate 10 and a plurality of electrode pads 25 (which will be described later) electrically connected to the mesas 19 on the back side of the substrate 10. The chip area of the laser diode 1 is usually determined on the basis of workability at the time of handling the chip, the layout of the chip, and the like and is, for example, about the area (150 μm×150 μm) of a square whose length L of one side is 150 μm.

The laser diode 1 has a semiconductor layer 20 on the top face side of the substrate 10. The semiconductor layer 20 is constructed by stacking, for example, from the substrate 10 side, a lower contact layer 11, a lower DBR layer 12, a lower cladding layer 13, an active layer 14, an upper cladding layer 15, a current narrowing layer 16, an upper DBR layer 17, and an upper contact layer 18.

The entire semiconductor layer 20 serves as a post-type mesa 19 (an optical function unit). The diameter of the mesa 19 is, for example, about 30 p.m. In a side face of the mesa 19, a plurality of steps are formed. For example, a step is formed in the interface between the lower contact layer 11 and the lower DBR layer 12, and the outer edge of the lower contact layer 11 serves as a base 11A. For example, a step is formed also in the interface between the lower DBR layer 12 and the lower cladding layer 13. The step does not have to be formed in the interface.

The substrate 10 is, for example, a GaAs substrate. The substrate 10 may have insulation property, high-resistance, or low resistance. The substrate 10 has a top face 10A, an under face 10B, and side faces 10C. The side face 10C has two corners 10D and two notches 10E. The two corners 10D are disposed so as to be opposed to each other on a diagonal line of the chip. The two notches 10E are disposed so as to be opposed to each other on the other diagonal line of the chip and formed at the corners of the chip (the laser diode 1). The notch 10E is, for example, a part of a through hole 10H formed by selectively etching the substrate 10 from the rear side in manufacturing process and is formed by, for example, cutting the substrate 10 along a cutting region 10F (which will be described later).

The lower contact layer 11 is made of, for example, n-type GaAs. The lower DBR layer . . . 12 is constructed by alternately stacking low-refractive-index layer (not shown) and a high-refractive-index layer (not shown). The low-refractive-index layer is made of, for example, n-type Alₓ₁Ga₁₋ₓ₁As (0<x1<1) having an optical thickness of λ/4 (λ denotes oscillation wavelength). On the other hand, the high-refractive-index layer is made of, for example, n-type Alₓ₂Ga₁₋ₓ₂As (0<x2<1) having an optical thickness of λ/4. Examples of the n-type impurity are silicon (Si) and selenium (Se).

The lower cladding layer 13 is made of, for example, Alₓ₃Ga₁₋ₓ₃As (0<x3<1). The active layer 14 is made of, for example, a GaAs-based material, and a region opposed to an unoxidized region 16B (which will be described later) serves as a light emission region 13A. The upper cladding layer 15 is made of, for example, Alₓ₄Ga₁₋ₓ₄As (0<x4<1). Although no impurity is preferably contained in the lower cladding layer 13, the active layer 14, and the upper cladding layer 15, p-type or n-type impurity may be contained. Examples of the p-type impurity are zinc (Zn), magnesium (Mg), and beryllium (Be).

The current narrowing layer 16 has an oxidized region 16A in a portion corresponding to the outer edge of the mesa 19 and has the unoxidized region 16B in a portion corresponding to the center of the mesa 19. The unoxidized region 16B is made of, for example, p-type Alₓ₅Ga₁₋ₓ₅As (0<x<1) and functions as a current injection region for injecting current from an upper electrode 22 (which will be described later) into the active layer 14. The oxidized region 16A is made of a material containing Al₂O₃ (aluminum oxide) and, as will be described later, is obtained by oxidizing high-concentration Al contained in a layer 16D to be oxidized from a side face of the mesa 19. Consequently, the oxidized region 16A functions as a current narrowing region of narrowing current to be injected to the active layer 14. The layer 16D to be oxidized is made of a material which is most easily oxidized from layers constructing the semiconductor layer 20.

The upper DBR layer 17 is formed by alternately stacking a low-refractive-index layer (not shown) and a high-refractive-index layer (not shown). The low-refractive-index layer is made of, for example, p-type Alₓ₆Ga₁₋ₓ₆As (0<x6<1) having an optical thickness of λ/4. On the other hand, the high-refractive-index layer is made of, for example, p-type Alₓ₇Ga₁₋ₓ₇As (0<x7<1) having an optical thickness of λ/4. The upper contact layer 18 is made of, for example, p-type GaAs.

In the laser diode 1 of the embodiment, for example, a protection film 21 is formed on the top face and side faces of the mesa 19 and the surface of the periphery region of the mesa 19. The annular-shaped upper electrode 22 is formed on the top face of the mesa 19 (the surface of the upper contact layer 18). An aperture 22A is formed in a center region of the upper electrode 22, that is, the region corresponding to the unoxidized region 16B. The upper electrode 22 is electrically connected to the top face of the mesa 19 (the surface of the upper contact layer 18).

Two metal layers 23 (first metal layers) are formed on the top face side of the substrate 10. The two metal layers 23 are formed in parts corresponding to the notches 10E in the substrate 10 and disposed so as to be opposed to each other with the mesa 19 in between. Each of the two metal layers 23 is formed at a corner of the chip and has, for example, a fan shape. Each of the metal layers 23 is formed in contact with the top face 10A of the substrate 10 and the surface of a metal layer 24 (which will be described later) and is electrically connected to the metal layer 24.

Two metal layers 24 (second metal layers) are formed on the rear side of the substrate 10. The two metal layers 24 are formed in the notches 10E in the substrate 10 so as to be in contact with the side faces 10C of the substrate 10 and the rear face of the metal layer 23. Each of the two metal layers 24 is formed at a corner of the chip and has, for example, a fan shape. The metal layers 23 and 24 are formed by, for example, cutting a through electrode 40 as will be described in detail later.

Two electrode pads 25 are formed on the under face 10B of the substrate 10. The two electrode pads 25 are pads for flip chip bonding for the laser diode 1. The two electrode pads 25 are formed near to the center on the rear face of the chip and have, for example, a circular shape. The electrode pads 25 are formed in contact with the metal layer 24. One of the electrode pads 25 is electrically connected to the upper electrode 22 via the metal layers 23 and 24 and a connection part 28 (which will be described later). That is, the metal layers 23 and 24 and the connection part 28 have the role of a wiring part that electrically connects one of the electrode pads 25 and the upper electrode 22. The other electrode pad 25 is electrically connected to a lower electrode 26 (which will be described later) via the metal layers 23 and 24 and a connection part 27 (which will be described later). That is, the metal layers 23 and 24 and the connection part 27 have the role of a wiring part that electrically connects the other electrode pad 25 and the lower electrode 26.

The lower electrode 26 is formed on the base 11A on the side face of the mesa 19. The lower electrode 26 is electrically connected to the base 11A (lower contact layer 11) and has, for example, a C shape. The connection part 27 is provided between the lower electrode 26 and one of the metal layers 23. The connection part 27 electrically connects the lower electrode 26 and one of the metal layers 23. The connection part 28 is provided between the upper electrode 22 and the metal layer 23 which is not connected to the lower electrode 26. The connection part 28 electrically connects the upper electrode 22 and the metal layer 23 which is not connected to the lower electrode 26.

The protection film 21 is formed of, for example, an insulating material such as oxide or nitride and brings isolation between the connection part 28 and the side face of the mesa 19. The metal layers 23 and 24, the electrode pad 25, and the connection parts 27 and 28 are constructed by stacking, for example, a titanium (Ti) layer, a platinum (Pt) layer, and a gold (Au) layer in this order. The lower electrode 26 has a structure obtained by, for example, stacking a layer of an alloy of gold (Au) and germanium (Ge), a nickel (Ni) layer, and a gold (Au) layer in order from the lower contact layer 11, and is electrically connected to the lower contact layer 11.

The laser diode 1 of the embodiment is manufactured, for example, as follows.

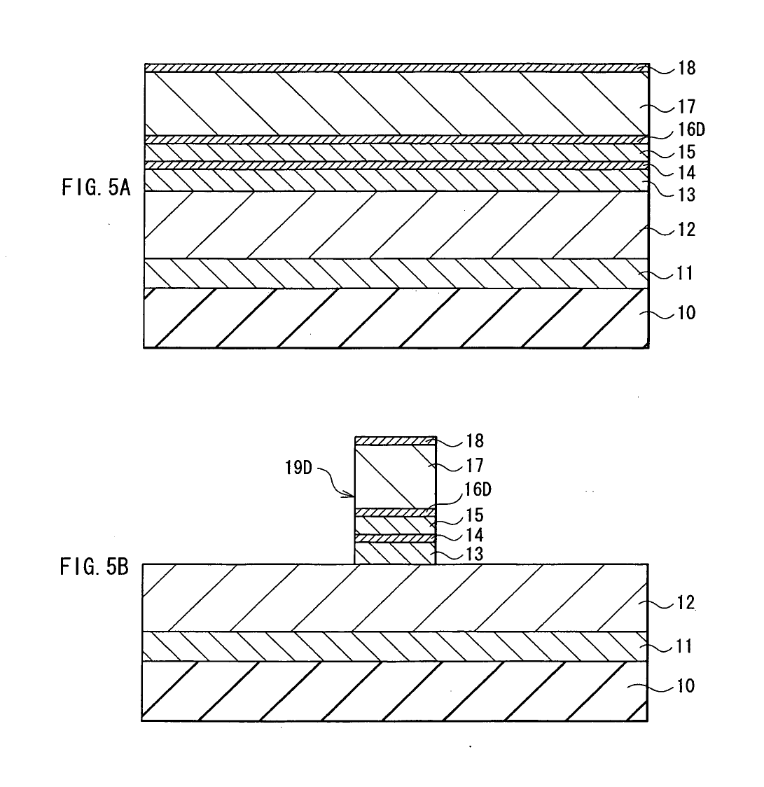

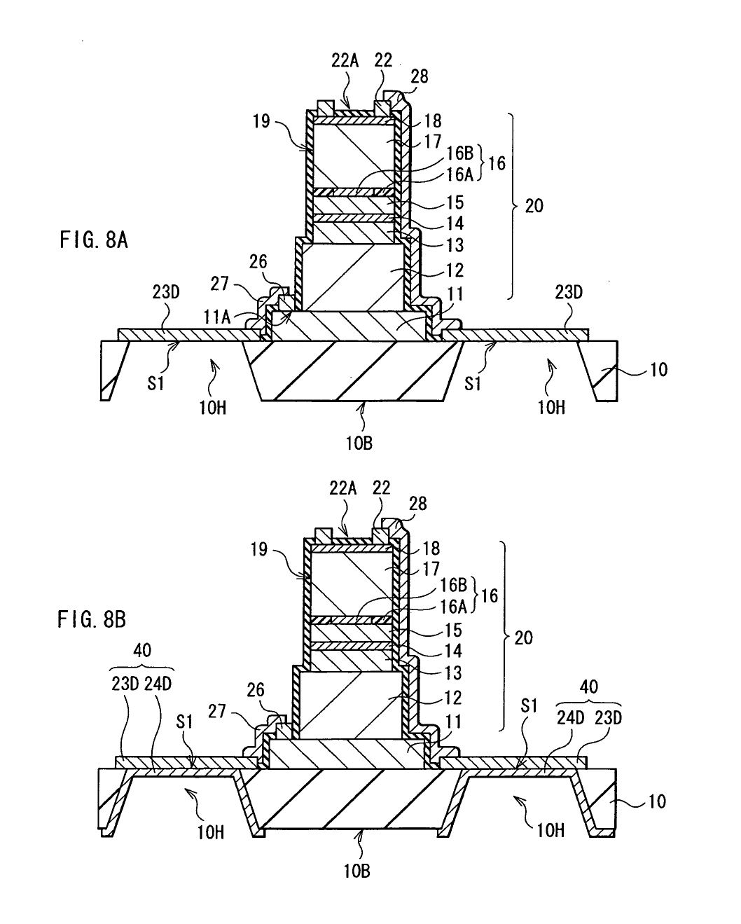

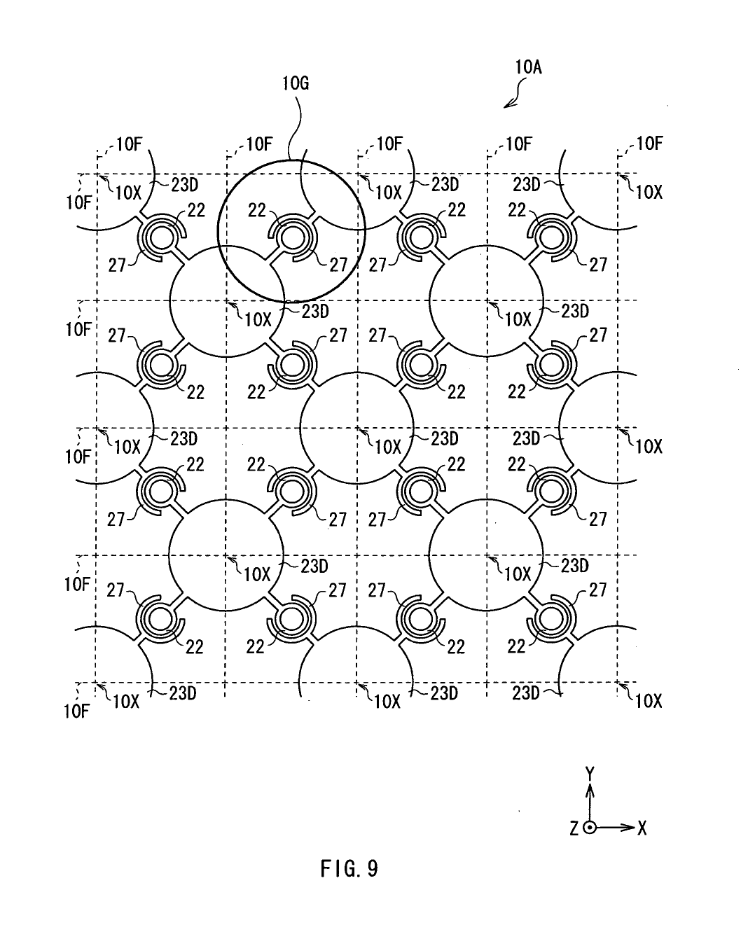

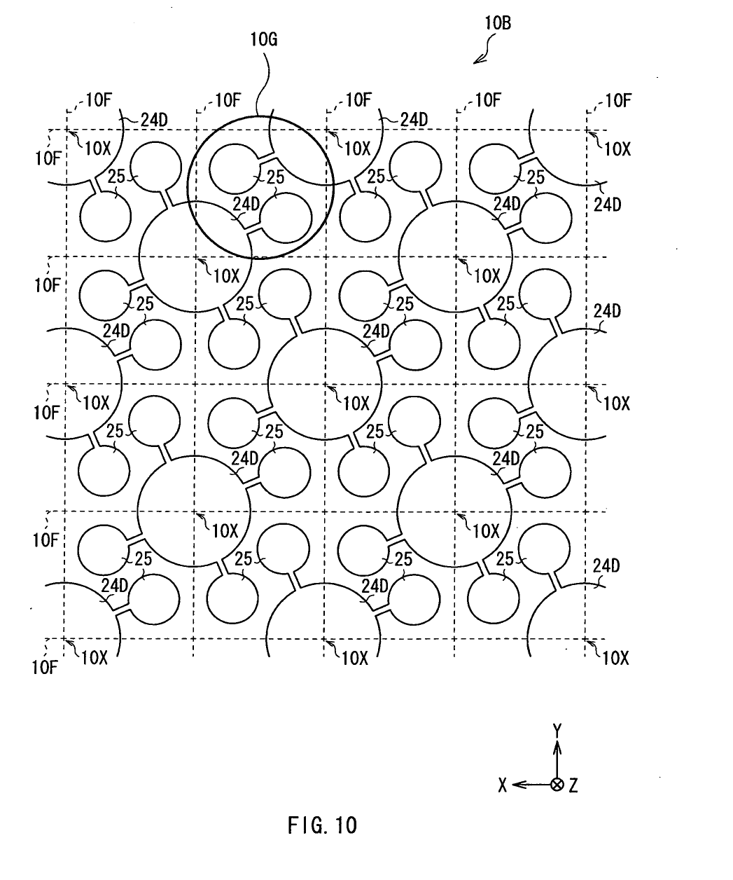

FIGS. 5A and 5B to FIG. 10 illustrate the manufacturing method in order of steps. Each of FIGS. 5A and 5B to FIGS. 8A and 8B illustrates a sectional configuration of a part of a substrate in the manufacturing process, FIG. 9 illustrates a part of the configuration of the top face of the substrate of FIGS. 8A and 8B, and FIG. 10 illustrates a part of the configuration of the bottom of the substrate of FIGS. 8A and 8B. Broken lines in FIGS. 9 and 10 illustrate places to be diced in order to divide the substrate 10 into small chips.

In the embodiment, the semiconductor layer 20 on the substrate 10 made of GaAs is formed by, for example, MOCVD (Metal Organic Chemical Vapor Deposition). As the material of a III-V group compound semiconductor, for example, trimethyl aluminum (TMA), trimethyl gallium (TMG), trimethyl indium (TMIn), or arsine (AsH₃) is used. As the material of donor impurity, for example, H₂Se is used. As the material of acceptor impurity, for example, dimethyl zinc (DMZ) is used.

First, on the top face 10A of the substrate 10, the lower contact layer 11, the lower DBR layer 12, the lower cladding layer 13, the active layer 14, the upper cladding layer 15, the layer 16D to be oxidized, the upper DBR layer 17, and the upper contact layer 18 are stacked in this order (FIG. 5A). The layer 16D to be oxidized is a layer which is oxidized in a oxidizing process to be described later to become the current narrowing layer 16 and is made of, for example, AlAs.

Next, for example, the lower cladding layer 13, the active layer 14, the upper cladding layer 15, the current narrowing layer 16, the upper DBR layer 17, and the upper contact layer 18 are selectively etched. By the etching, the post-shaped mesa 19D is formed in each chip region (not shown) surrounded by a lattice-shaped cutting region (not shown) along which the substrate 10 is to be cut (FIG. 5B). As a result, the layer 16D to be oxidized is exposed in side faces of the mesa 19D.

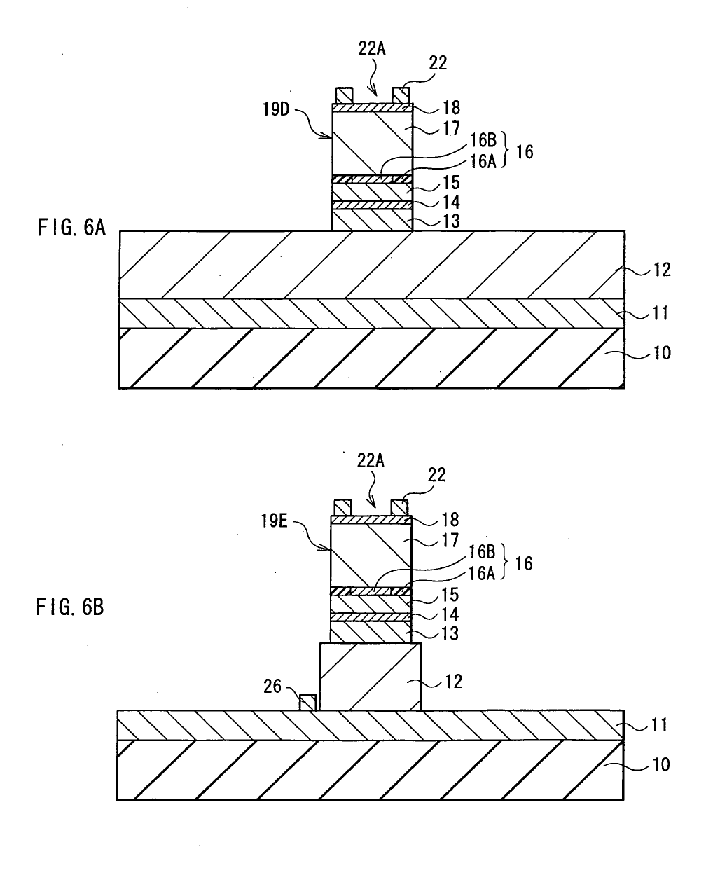

Next, the oxidizing process is performed at high temperature in water-vapor atmosphere to selectively oxidize Al in the layer 16D to be oxidized from the side faces of the mesa 19D (FIG. 6A). By the oxidization, the outer edge region of the mesa 19D in the layer 16D to be oxidized becomes the oxidized region 16A containing Al₂O₃ (aluminum oxide), and the center region in the mesa 19D becomes the unoxidized region 16B. In such a manner, the current narrowing layer 16 is formed. Subsequently, the annular upper electrode 22 is formed on the top face of the mesa 19D (the top face of the upper contact layer 18) (FIG. 6A).

Next, for example, a portion which is not opposed to the mesa 19D in the lower DBR layer 12 is selectively etched. By the etching, the post-shaped mesa 19E having a step in its side face is formed (FIG. 6B). Subsequently, around the mesa 19E, the C-shaped lower electrode 26 is formed so as to surround the mesa 19E (FIG. 6B).

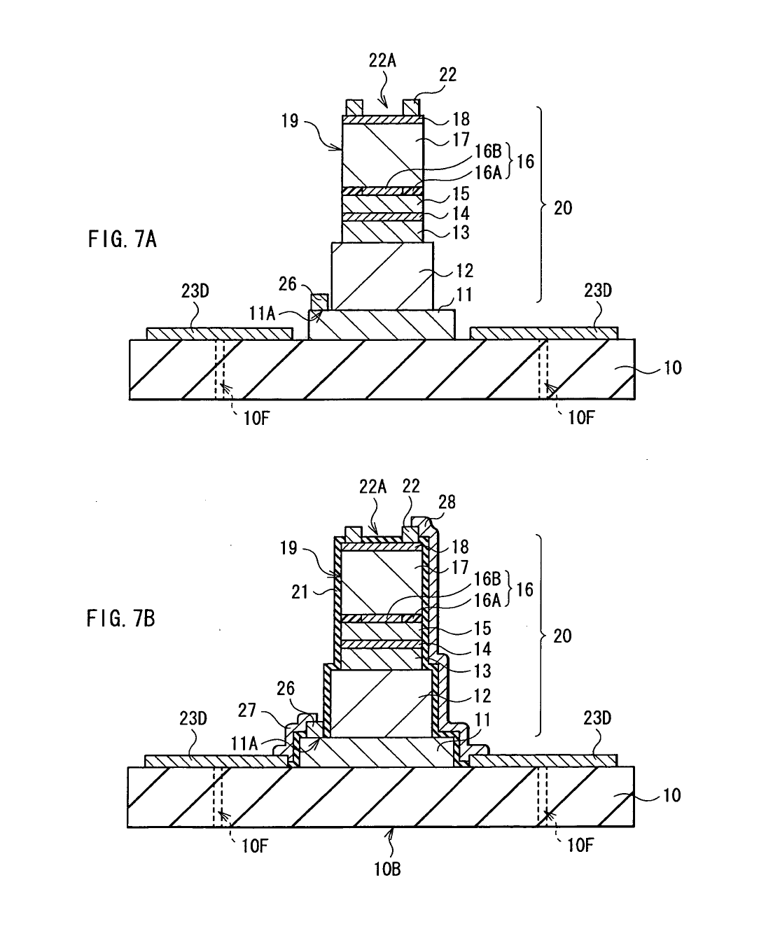

Next, a portion which is not opposed to the mesa 19E and the lower electrode 26 in the lower contact layer 11 is selectively etched. By the etching, on the top face 10A of the substrate 10, the post-shaped mesa 19 having the base 11A is formed on the side face (FIG. 7A). Subsequently, two metal layers 23D are formed over the cutting region 10F in the top face of the substrate 10 (FIG. 7A).

The cutting region 10F is a region along which the substrate 10 is cut at the time of dicing the substrate 10 into chips (laser diodes 1) in a later process. The cutting regions 10F are designed in lattice on the top face of the substrate 10. The metal layer 23D is cut at the time of dicing the substrate 10 to thereby become the metal layer 23. The metal layer 23D has, for example, a circular shape and its diameter is, for example, about 100 μm.

Next, the protection film 21 covering the top face, the side faces and the peripheral surface of the mesa 19 is formed (FIG. 7B). Subsequently, the connection part 27 electrically connecting the lower electrode 26 and one of the metal layers 23 and the connection part 28 electrically connecting the upper electrode 22 and one of the metal layers 23 which is not connected to the lower electrode 26 are formed (FIG. 7B). After that, the under face 10B of the substrate 10 is lapped to adjust the substrate 10 to a predetermined thickness. The thickness of the substrate 10 is preferably to a degree that the through holes 10H are easily formed in a later process.

Next, a plurality of through holes 10H are formed in the substrate 10. Concretely, a through hole 10H from which a surface Si on the substrate 10 side of the metal layer 23D is exposed is formed in a portion including the cutting region 10F in the substrate 10 (FIG. 8A). That is, the through hole 10H is formed over the cutting region 10F. Subsequently, a plurality of electrode pads 25 (not shown) are formed on the under face 10B of the substrate 10. As described above, the chip regions are regions surrounded by the lattice-shaped cutting region 10F.

Next, the metal layer 24D for electrically connecting the metal layer 23D and the electrode pad 25 via the through hole 10H is formed. In such a manner, the through electrode 40 is formed on the substrate 10. The electrode pad 25 and the metal layer 24D may be formed simultaneously (in a lump). The metal layer 24D is cut at the time of dicing the substrate 10 to thereby become the metal layer 24. The metal layer 24D has, for example, a circular shape when viewed from the under face 10B side of the substrate 10 and its diameter is, for example, about 100 μm like the metal layer 23D.

FIG. 9 illustrates an example of layout on the top face 10A side of the substrate 10 at the stage where the metal layer 23D is formed. FIG. 10 illustrates an example of layout on the under face 10B side of the substrate 10 at the stage where the metal layer 24D is formed. The metal layers 23D and 24D are formed over the cutting regions 10F as described above and, further, formed on an intersection 10× of the cutting regions 10F. That is, the metal layers 23D and 24D (through electrode 40) are not formed in each chip region 10G surrounded by the cutting region 10F but formed over the cutting regions 10F as borders of the chip regions 10G.

Although not shown, the substrate 10 is cut along the cutting regions 10F, and the metal layers 23D and 24D (through electrodes 40) are cut, thereby dicing the substrate 10 into chips. In such a manner, the laser diode 1 of the embodiment is manufactured.

Next, the action and effect of the laser diode 1 will be described.

In the laser diode 1, when a predetermined voltage is applied across the upper electrode 22 and the lower electrode 26, current is injected to the active layer 14 via the unoxidized region 16B, and light is emitted by recombination of electrons and holes. The light is reflected by the pair of lower and upper DBR layers 17 and 12, laser oscillation is generated at a predetermined wavelength, and the light is emitted as a laser beam from the aperture 22A to the outside.

In related art, at the time of manufacturing a device which is capable of flip-chip-mounted, through electrodes each having a diameter of about 100 μm are formed in a chip region (a region surrounded by a cutting region) on a wafer. Consequently, the area of the chip region is about 300 μm×300 μm of a square whose one side has a length of 300 μm, and the yield from one wafer is inevitably low.

On the other hand, in the embodiment, in the manufacturing process, the metal layers 23D and 24D (through electrode 40) are formed over the cutting region 10F as the boundary of the chip regions 10G. After cutting the through electrodes 40, a part of the through electrodes 40 remained on the side face 10C may be used as wiring. Therefore, the size of the chip region 10G does not have to be set to a size in which the through electrode 40 is able to be formed. For example, the area of the chip region 10G may be set to the area (150 μm×150 μm) of a square whose one side has a length L of 150 μm. As a result, as compared with the existing case that through electrodes are formed in the chip, the chip size is allowed to be made smaller, and the yield improves.

### Modification of First Embodiment

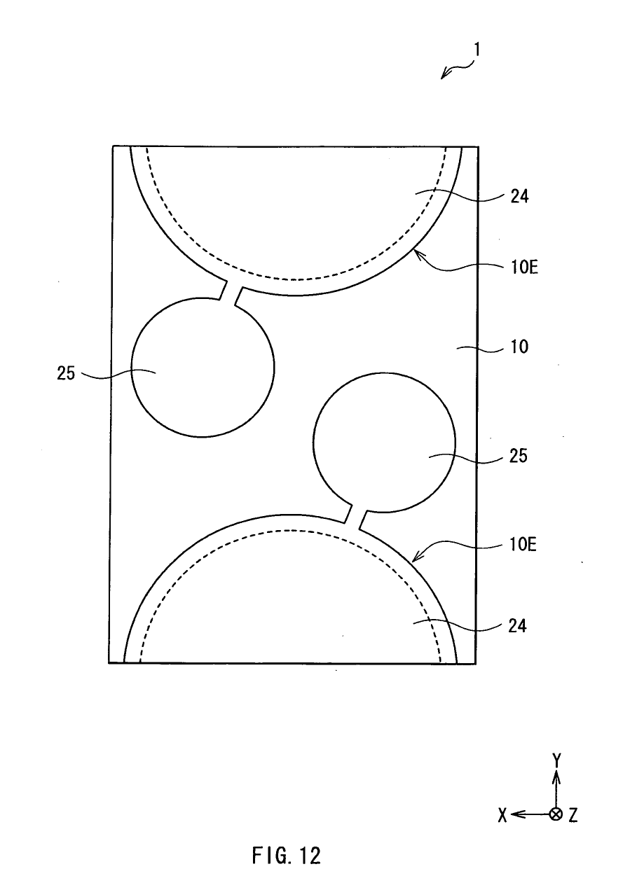

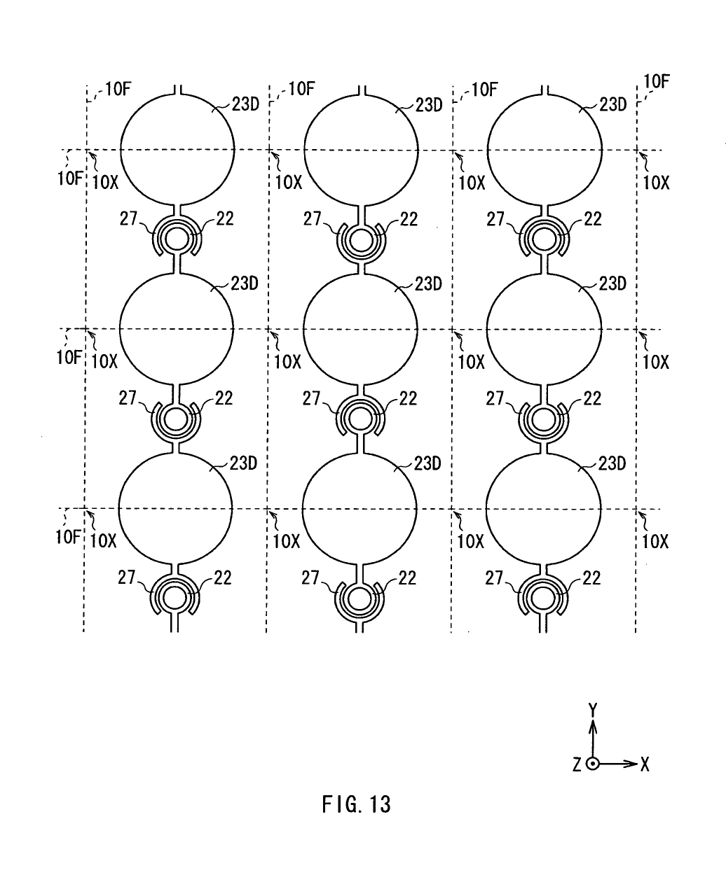

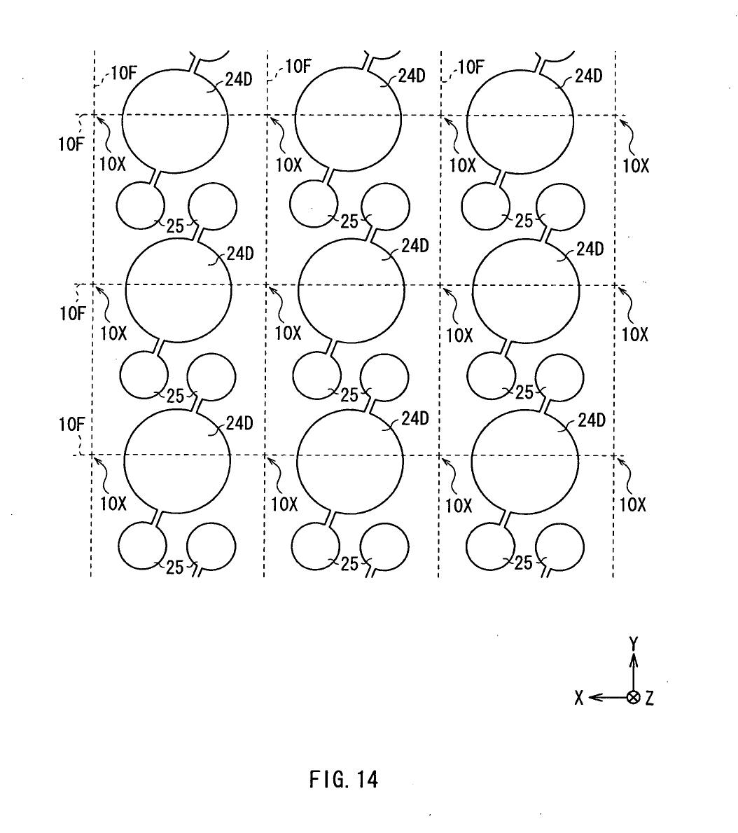

Although the notch 10E is formed at a corner of the chip in the embodiment, for example, as illustrated in FIGS. 11 and 12, it may be formed in a side of the chip. In such a case, in the manufacturing process, for example, as illustrated in FIGS. 13 and 14, it is sufficient to form the metal layers 23D and 24D over a part except for the intersection 10× in the cutting region 10F.

### Second Embodiment

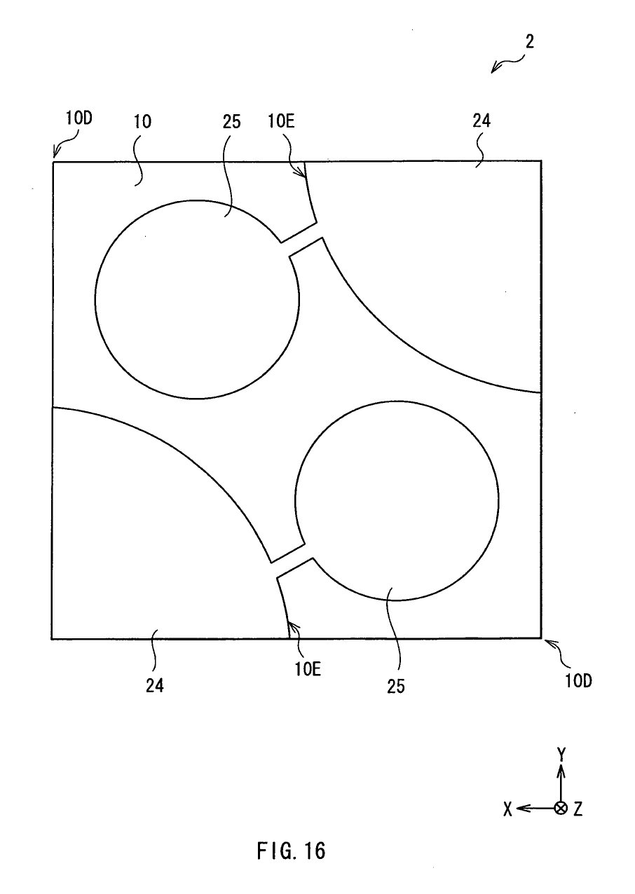

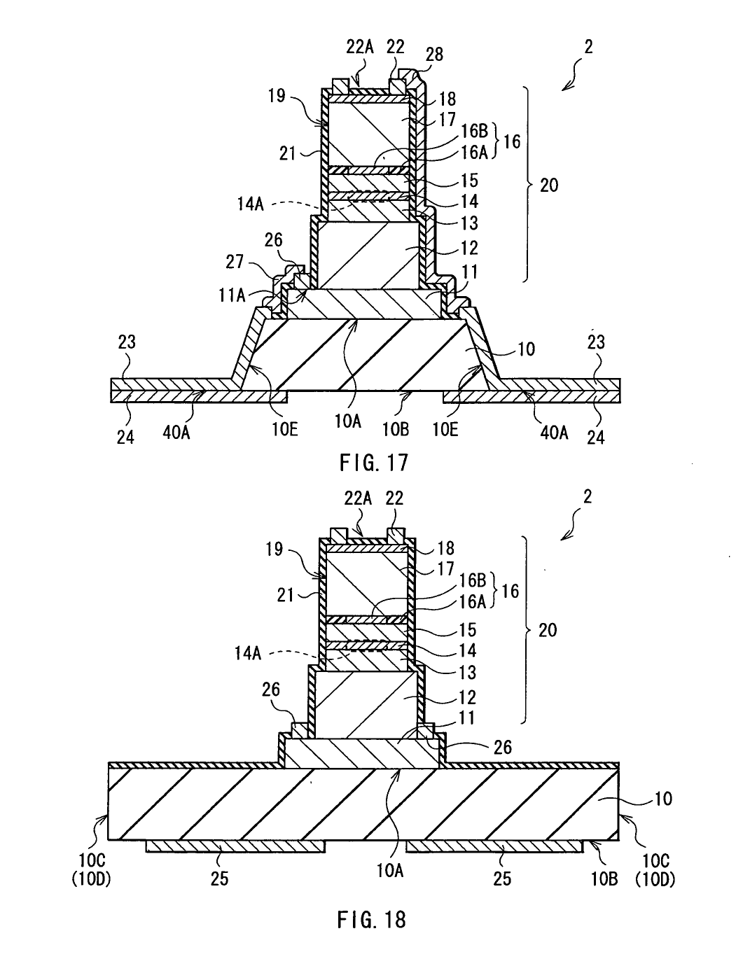

A vertical cavity surface laser diode 2 according to a second embodiment of the present invention will now be described. FIG. 15 is a top view of the laser diode 2. FIG. 16 is a back side view of the laser diode 2 of FIG. 15. FIG. 17 illustrates a sectional configuration taken along line A-A of the laser diode 2 of FIG. 15. FIG. 18 illustrates a sectional configuration taken along line B-B of the laser diode 2 of FIG. 15.

Like the laser diode 1 of the foregoing embodiment, the laser diode 2 is a chip having a structure suitable for flip chip bonding. For example, the laser diode 2 has one or more mesas 19 on the top face 10A side of the substrate 10 and has a plurality of electrode pads 25 electrically connected to the mesas 19 on the back side of the substrate 10. The laser diode 2 is different from the laser diode 1 in which a joint face 40A is disposed in flush with the top face 10A of the substrate 10 with respect to the point that the joint face 40A between the metal layers 23 and 24 is disposed in flush with the under face 10B of the substrate 10. In the following, the point different from the foregoing embodiment will be mainly described, and description on points common to the foregoing embodiment will not be properly given.

In the embodiment, as described above, the joint face 40A is disposed in flush with the under face 10B of the substrate 10. Therefore, no roughness caused by the notch 10E exists on the rear face side of the laser diode 2, and the rear face side is almost flat.

The laser diode 2 according to the embodiment may be manufactured as follows.

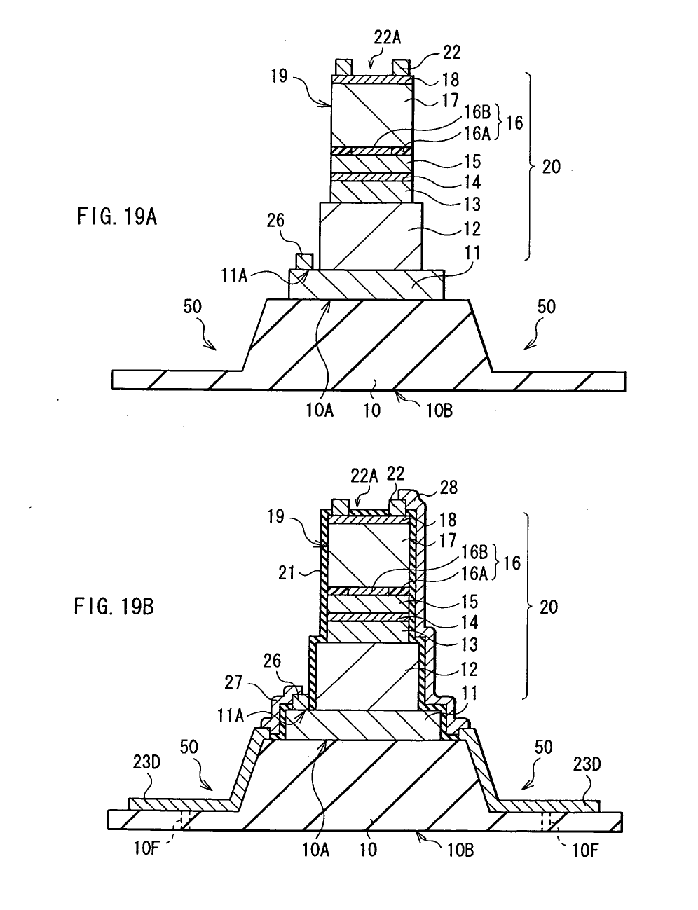

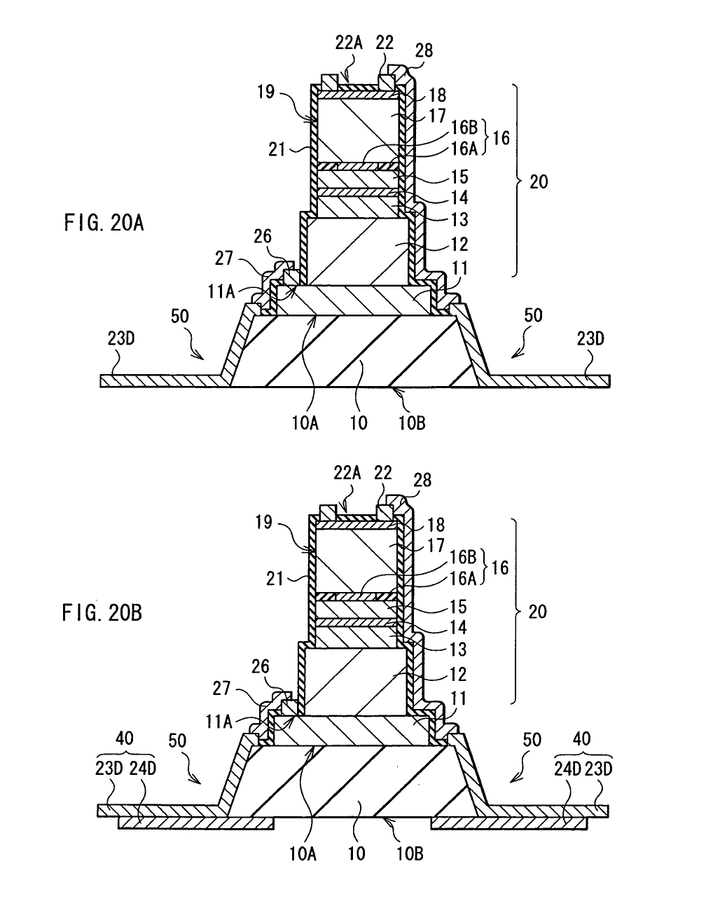

FIGS. 19A and 19B and FIGS. 20A and 20B illustrate the manufacturing method in order of steps. FIGS. 19A and 19B and FIGS. 20A and 20B show sectional configurations of a part of the substrate of the manufacturing process.

First, in a manner similar to the above-described embodiment, parts up to the lower electrode 26 are formed (FIGS. 5A, 5B, 6A and 6B).

Next, for example, the portions which are not opposed to the mesa 19E and the lower electrode 26 in the lower contact layer 11 are selectively etched, thereby forming the post-shaped mesa 19 having the base 11A on its side face (FIG. 19A). Subsequently, a plurality of dents 50 are formed in the substrate 10. More specifically, two dents 50 are formed in the periphery of the mesa 19 and formed in a place including the cutting region 10F in the substrate 10 per mesa 19 (FIG. 19A). That is, the dent 50 is formed so as to extend over the cutting region 10F. The dent 50 has a depth to a degree that it does not penetrate the substrate 10. The substrate 10 remains thinly between the bottom face of the dent 50 and the under face 10B of the substrate 10.

Next, the two metal layers 23D are formed so as to extend from the top face 10A of the substrate 10 to the bottom face of the dent 50 and so as to extend over the cutting region 10F in the top face 10A of the substrate 10 (FIG. 19B). The metal layer 23D is cut at the time of dicing the substrate 10 to thereby become the metal layer 23. The metal layer 23D has, for example, a circular shape and its diameter is, for example, about 100 μm.

Next, the protection film 21 covering the top face, the side faces and the peripheral surface of the mesa 19 is formed (FIG. 19B). Subsequently, the connection parts 27 and 28 are formed (FIG. 19B). After that, the under face 10B of the substrate 10 is lapped to expose the face on the substrate 10 side in the metal layer 23D (FIG. 19B).

Next, a plurality of electrode pads 25 (not shown) are formed in the under face 10B of the substrate 10. After that, the metal layer 24D for electrically connecting the metal layer 23D and the electrode pads 25 is formed. In such a manner, the through electrode 40 is formed on the substrate 10. The electrode pad 25 and the metal layer 24D may be formed simultaneously (in a lump). The metal layer 24D is cut at the time of dicing the substrate 10 and, by the cutting of the metal layer 24D, becomes the metal layer 24. The metal layer 24D has, for example, a circular shape when viewed from the under face 10B side of the substrate 10 and its diameter is, for example, about 100 μm like the metal layer 23D.

Although not illustrated, the substrate 10 is cut along the cutting regions 10F, and the metal layers 23D and 24D (through electrodes 40) are cut, thereby dicing the substrate 10 into chips. In such a manner, the laser diode 2 of the embodiment is manufactured.

Next, the action and effect of the laser diode 2 will be described.

In the laser diode 2, when a predetermined voltage is applied across the upper electrode 22 and the lower electrode 26, current is injected to the active layer 14 via the unoxidized region 16B, and light is emitted by recombination of electrons and holes. The light is reflected by the pair of lower and upper DBR layers 12 and 17, laser oscillation is generated at a predetermined wavelength, and the light is emitted as a laser beam from the aperture 22A to the outside.

In the second embodiment, in a manner similar to the foregoing embodiment, in the manufacturing process, the metal layers 23D and 24D (through electrode 40) are formed over the cutting region 10F as the boundary of the chip regions 10G. By cutting the through electrodes 40, chips are obtained. After cutting the through electrode 40, a part of the through electrode 40 remained on the side face 10C may be used as wiring. Therefore, the size of the chip region 10G does not have to be set to a size in which the through electrode 40 is able to be formed. For example, the area of the chip region 10G may be set to the area (150 μm×150 μm) of a square whose one side has a length L of 150 p.m. As a result, as compared with the existing case that a through electrode is formed in the chip, the chip size is allowed to be made smaller, and the yield improves.

### Modification of Second Embodiment

Although the notch 10E is formed at a corner of the chip in the second embodiment, for example, like in the modification of the first embodiment, it may be formed in a side of the chip.

In place of lapping the under face 10B of the substrate 10 after formation of the connection parts 27 and 28 in the manufacturing process of the second embodiment, another process may be performed. For example, by etching all or selectively etching a part of the region opposed to the bottom face of the dent 50 in the under face 10B of the substrate 10, the face on the bottom face side of the dent 50 in the metal layer 23D may be exposed.

Although the present invention has been described by the embodiments and their modifications, the invention is not limited to the embodiments but may be variously modified.

For example, although the present invention has been described using a vertical cavity surface laser diode as an example in the foregoing embodiments and the like, the invention may be also applied to another semiconductor device such as a light emitting diode or a photodiode.

Although the present invention has been described using the AlGaAs compound laser diode as an example in the foregoing embodiments and the like, the invention may be also applied to another compound laser diode such as a GaInP, AlGaInP, InGaAs, GaInP, InP, GaInN, or GaInNAs compound laser diode.

The present application contains subject matter related to that disclosed in Japanese Priority Patent Application JP 2009-172407 filed in the Japan Patent Office on Jul. 23, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising:
a substrate having a top face, an under face, and side faces;
an optical function unit formed on the top face;
a plurality of electrode pads formed on the under face; and
a wiring formed on at least the side face and electrically connecting the optical function unit and at least one of the plurality of electrode pads.

2. The semiconductor device according to claim 1, wherein the wiring is formed by cutting a through electrode.

3. The semiconductor device according to claim 1, wherein the wiring is formed by making a first metal layer formed on the top face side and a second metal layer formed on the under face side come in contact with each other.

4. The semiconductor device according to claim 1, wherein the substrate has a notch, and
the wiring is formed at least in the notch.

5. The semiconductor device according to claim 1, wherein the notch is formed at a corner of the semiconductor device.

6. The semiconductor device according to claim 1, wherein the notch is formed in a side of the semiconductor device.

7. The semiconductor device according to claim 1, wherein the optical function unit is a laser diode, a light-emitting diode, or a photodiode.

8. A method of manufacturing a semiconductor device, comprising:
a first step of forming an optical function unit on a top face of a substrate having the top face and an under face in each of chip regions surrounded by cutting regions in a lattice shape along which the substrate is to be cut, and forming a plurality of first metal layers over the cutting regions in the top face;
a second step of forming through holes from which a face on the substrate side of the first metal layer is exposed in places including the cutting regions in the substrate, forming a plurality of electrode pads in the under face in each of the chip regions, and forming a second metal layer that electrically connects the first metal layer and the electrode pads via the through holes; and
a third step of cutting the substrate along the cutting regions and cutting at least the first metal layer out of the first and second metal layers to dice the substrate into chips.

9. The method of manufacturing a semiconductor device according to claim 8, wherein the plurality of first metal layers are formed in intersections of the cutting regions in the top face in the first step.

10. The method of manufacturing a semiconductor device according to claim 8, wherein the plurality of first metal layers are formed over portions other than intersections of the cutting regions in the top face in the first step.

11. A method of manufacturing a semiconductor device, comprising:
a first step of forming an optical function unit on a top face of a substrate having the top face and an under face in each of chip regions surrounded by cutting regions in a lattice shape along which the substrate is to be cut, forming a plurality of dents over the cutting regions in the top face of the substrate, and forming a plurality of metal layers extending from the optical function unit to a bottom face of the dent;
a second step of exposing a face on a bottom face side of the dent in the metal layer by etching the substrate, after that, forming a plurality of electrode pads on the under face of the substrate in each of the chip regions, and making at least one of the plurality of electrode pads formed in each of the chip regions come in contact with the metal layer; and
a third step of cutting the substrate along the cutting regions and cutting the dents to dice the substrate into chips.

12. The method of manufacturing a semiconductor device according to claim 11, wherein in the second step, the face on the under face side of the dent in the metal layer is exposed by lapping the under face.

13. The method of manufacturing a semiconductor device according to claim 11, wherein in the second step, the face on the bottom face side of the dent in the metal layer is exposed by etching all of a region opposed to the bottom face of the dent in the under face or by selectively etching a part of the region.
